(19) United States
(12) Patent Application Publication
(10) Pub. No.: US 2019/0341513 A1
(43) Pub. Date: Nov. 7, 2019

(54) EXTRUDED SOLAR POWER BACK PANEL AND MANUFACTURING METHOD THEREOF

(71) Applicant: SUZHOU DUCHAMPS ADVANCED MATERIALS CO., LTD., Suzhou, Jiangsu (CN)

(72) Inventors: Jijiang LUO, Suzhou (CN); Shuzhen FU, Suzhou (CN); Haitao GUO, Suzhou (CN)

(73) Assignee: SUZHOU DUCHAMPS ADVANCED MATERIALS CO., LTD., Suzhou, Jiangsu (CN)

(21) Appl. No.: 16/088,286

(22) PCT Filed: Aug. 10, 2017
(86) PCT No.: PCT/CN2017/096703

§ 371 Date: Sep. 25, 2018

(30) Foreign Application Priority Data
Aug. 18, 2016 (CN) 201610685022.5
Jul. 17, 2017 (CN) 201710582051.3

(51) Int. Cl. H01L 31/049; B32B 27/08; B32B 27/32; B29C 48/00; B29C 48/21; H01L 31/048; C08L 23/06; C08L 23/12

(52) U.S. Cl. CPC H01L 31/049; B32B 27/08; B32B 27/32; B29C 48/022; B29K 2023/0633; H01L 31/0481; C08L 23/06; C08L 23/12; B32B 2457/12; B29C 48/21

(57) ABSTRACT

An extruded solar power back panel: an inner, middle, and outer layer arranged from the inside to the outside sequentially with a mass ratio of 10-40:40-80:10-40. Total thickness of the extruded solar power back panel is 0.1-0.6 mm. Highly rigid polypropylene added to inner layer ensures the bonding force between back panel and adhesive film, and improves inter-layer bonding force between back panel and polypropylene material in middle layer. Polyethylene, or a co-polymer thereof, added to the middle and outer layers, achieves excellent adhesion to polyethylene in inner layer, further improving inter-layer bonding force and low temperature thermal shock resistance of back panel. Added grafting material improves uniformity and inter-layer bonding force of product, increases the surface tension of back panel after corona treatment, and increases bonding force between back panel and silica gel used for sealing frame of solar cell.

### BACKGROUND

The present invention relates to an extruded solar power back panel and a manufacturing method thereof.

With the exhaustion of non-renewable energies and increasingly severe environmental problems, solar energy, as a clean energy, has attracted unprecedented attention. Solar power generation (also known as photovoltaic power generation) is one of the main routes to effectively utilize solar energy. The reliability of solar cells (also known as photovoltaic cells), a core part for solar power generation, directly determines the efficacy of solar power generation.

According to the prior art, a solar cell generally consists of an upper cover, a film, a cell sheet, a film, and a solar power back panel, wherein the solar power back panel is an important part of the solar cell. On one hand, the solar power back panel bonds and packages components of the solar cell, and on the other hand, the solar power back panel protects the solar cell, prevents water vapor penetration, improves the solar cell's resistance to moisture, heat, and ageing and photoelectric conversion efficiency, and extends the service life of the solar cell.

At present, there are mainly three processes for manufacturing solar power back panels, i.e., the lamination method, the coating method, and the multi-layer co-extrusion method. According to the lamination method, an adhesive is used to directly laminate a bonding layer (polyolefin or EVA resin) and a fluorine-containing weather-resistant layer onto two sides of a polyester film substrate, respectively; according to the coating method, a fluorocarbon coating is coated onto a polyester film substrate; according to multi-layer co-extrusion, raw materials of the layers are mixed homogeneously, melted at high temperature, and extruded by a screw extruder. Since the solar power back panel is directly exposed to the air and under adverse environmental conditions, all existing products are of a multi-layer composite structure.

According to the prior art, materials used for solar power back panels mainly include polyester film substrates, ethylene-vinyl acetate, and fluorine-containing weather-resistant layers. However, main molecular chains of polyester and ethylene-vinyl acetate contain a great number of ester groups and tend to be hydrolyzed. Despite of modification processing, it is still difficult to meet solar power back panels' requirements for resistance to moisture, heat, and ageing; at the same time, a fluorine-containing weather-resistant layer is expensive and has poor bonding performance, which weakens the performance of solar power back panels. Polyolefin is a polymer of olefins, which has an abundant source of raw materials, low price, good abrasion resistance, and excellent electric insulating performance. Moreover, the molecules have no polarity and extremely low water absorption, and can meet solar power back panels' requirements for high blocking performance, resistance to ageing, and resistance to weather. The application of polyolefin in a solar power back panel can lead to excellent performance. For example, the Chinese Invention Patent CN103895304A discloses a three-layer co-extruded back panel, which has an inner layer comprising polyethylene resin or ethylene-vinyl acetate copolymer resin, a middle layer comprising a composition of polyethylene and polypropylene resins, and the outer layer being a polypropylene resin composition; as such, a solar power back panel is obtained through melting and extrusion.

However, it has been found through practical applications that polyethylene and ethylene-vinyl acetate in the inner layer have relatively high melt viscosity and can ensure the bonding force between the inner layer of the solar power back panel and an EVA film, but these two materials have relatively low rigidity and relatively weak bonding force with the polypropylene material in the middle layer that is relatively rigid. As a result, the interlayer bonding force is low, which then reduces the mechanical strength of the solar power back panel; meanwhile, the polypropylene resin in the outer layer has relatively low impact resistance at a low temperature, leading to poor low impact resistance at a low temperature of the solar power back panel.

Therefore, it is necessary to develop a new back panel with satisfying interlayer bonding force, which can also ensure that the back panel meets the requirements for high bonding capability, high mechanical strength, and high impact resistance at a low temperature for back panels.

### SUMMARY

The objective of the present invention is to provide an extruded solar power back panel and a manufacturing method thereof.

To achieve the above objective, the present invention employs the following technical solution: an extruded solar power back panel, comprising an inner layer, a middle layer, and an outer layer arranged from the inside to the outside sequentially, the mass ratio of the inner layer to the middle layer to the outer layer being 10-40:40-80:10-40; and

the total thickness of the extruded solar power back panel is 0.1-0.6 mm;

wherein the inner layer comprises the following constituents in parts by mass:

| | |
|---|---|
| polyethylene | 15-85 parts |
| polypropylene | 15-85 parts |
| filler | 0.5-20 parts |
| additive | 0.1-5 parts; |

the polyethylene is one or a mixture of several selected from the group consisting of linear low-density polyethylene, low-density polyethylene, medium-density polyethylene, and copolymers thereof, its density is 0.860-0.940 g/cm3, its DSC melting point is 50-135° C., and its melt flow rate is 0.1-40 g/10 min (2.16 kg, 190° C.), and high-density polyethylene, ultra high-density polyethylene, or a copolymer thereof may be selected, and the density is greater than 0.940 g/cm³; the polypropylene is one or a mixture of several selected from the group consisting of polypropylene homopolymer, polypropylene random copolymer, and polypropylene block copolymer, its DSC melting point is 110-168° C., and its melt flow rate is 0.1-20 g/10 min (2.16 kg, 230° C.); the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;

the middle layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of several selected from the group consisting of polypropylene homopolymer, polypropylene random copolymer, and polypropylene block copolymer; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;

the outer layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of two selected from the group consisting of polypropylene homopolymer and polypropylene block copolymer, or polypropylene random copolymer may be selected; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers.

Preferably, polyethylene in the constituents of the aforementioned middle layer is 1-10 parts.

Preferably, polyethylene in the constituents of the outer layer is 1-10 parts.

Positions of the middle layer and the outer layer may be switched.

Antioxidants can prevent organic compound materials from deterioration caused by oxidation. The thermal oxidation process of an organic compound is a series of chain reactions of radicals. Under the action of heat, light and oxygen, chemical bonds are broken to produce active radicals and hydrogen peroxides. The hydrogen peroxides undergo decomposition reactions to produce alkoxy radicals and hydroxy radicals. These radicals can trigger a series of chain reactions of radicals, such that fundamental changes take place to the structure and properties of the organic compound. An antioxidant can eliminate newly produced radicals or promote decomposition of hydrogen peroxides, prevent chain reactions, effectively inhibit the ageing of polymers due to thermal oxidation, and prevent a back panel from yellowing in use.

The use of a light stabilizer and a UV absorbent together can achieve good synergistic effect and an effect that cannot be achieved by single constituents, which can effectively prevent a material from yellowing and stop the loss of physical capabilities, thereby further improving the effect of light stabilization.

The back panel according to the present invention can be used independently as a back panel, or can be used as a substrate film for a solar power back panel to make a composite back panel with other materials, such as fluorine-contained films and PET.

In the above technical solutions, the silane coupling agent is one or more selected from the group consisting of vinyl trimethoxysilane, vinyl triethoxysilane, isobutyl triethoxysilane, 3-aminopropyl triethoxysilane, 3-aminopropyl trimethoxysilane and 3-glycidyl aminopropyl trimethoxysilane, vinyl tris(β-methoxyethoxy) silane, γ-methacryloyloxypropyl trimethoxy silane, γ-mercapto-propyl triethoxysilane, N-n-amino ethyl-γ-aminopropylmethyl dimethoxysilane, N-(β-amino ethyl)-γ-aminopropyl triethoxysilane, N-β-(amino ethyl)-γ-amino propyl trimethoxysilane, N-(β-amino ethyl)-γ-amino propyl triethoxysilane, γ-aminopropyl methyl diethoxysilane, diethylamino methyl triethoxysilane, anilino methyl triethoxysilane, dichloro methyl triethoxysilane, bis(γ-triethoxysilylpropyl) tetrasulfide, phenyl trimethoxy silane, phenyl triethoxysilane, and methyl triethoxysilane.

In the above technical solutions, the antioxidant is one or more selected from the group consisting of bis(3,5-tert-butyl-4-hydroxy phenyl) thioether, 2,6-tert-butyl-4-methyl phenol, 2,8-di-tert-butyl-4-methyl phenol, pentaerythritol tetra[β-(3′,5′-di-tert-butyl-4-hydroxy phenyl) propionate], tert-butyl p-hydroxyanisole, 2,6-di-tert-butylated hydroxy toluene, tert-butylhydroquinone, 2,6-di-tert-butyl phenol, 2,2′-thio bis(4-methyl-6-tert-butyl phenol), 4,4′-thiobis(6-tert-butyl m-cresol), N,N′-di-s-butyl p-phenylenediamine, s-butyl p-phenylenediamine, 4,4′-methylene bis(2,6-di-tert-butyl phenol), 2,2′-methylene bis(4-methyl-6-tert-butyl phenol), didodecyl thiodipropionate, dilauryl thiodipropionate, 2,6-di-tert-butyl-p-cresol, 2,6-di-tert-butyl-p-cresol, 3,5-di-tert-butyl-4-hydroxy benzyl diethyl phosphonate, 4-[(4,6-dioctylthio-1,3,5-triazine-2-yl)amino]-2,6-di-tert-butyl phenol, and 1,3,5-trimethyl-2,4,6-tris(3,5-di-tert-butyl-4-hydroxy benzyl)benzene.

In the above technical solutions, the UV absorbent is one or more selected from the group consisting of phenyl salicylate, 2-(2′-hydroxy-5′-methylphenyl)benzotriazole, 2,4-dihydroxy benzophenone, 2-hydroxy-4-methoxy benzophenone, 2-hydroxy-4-n-octoxyl benzophenone, resorcinol mono-benzoate, phenyl salicylate, 2-(2-hydroxy-3-tert-butyl-5-methylphenyl)-5-chloro benzotriazole, 2-(2′-hydroxy-3′,5′-di-tert-phenyl)-5-chloro benzotriazole, 2-(2-hydroxy-3,5-di-tert-pentyl phenyl) benzotriazole, 2-(2′-hydroxy-4′-benzoyloxy phenyl)-S-chloro-2H-benzotriazole, 2-(4,6-bis(2,4-dimethylphenyl)-1,3,5-triazine-2-yl)-5-octoxyl phenol, and 2-(4,6-diphenyl-1,3,5-triazine-2)-5-n-hexyloxy phenol.

In the above technical solutions, the light stabilizer is one or more selected from the group consisting of bis(2,2,6,6-tetramethyl-4-piperidinyl) sebacate, tris(1,2,2,6,6,-pentamethyl piperidinyl) phosphite, hexamethylphosphoramide, 4-benzoyloxy-2,2,6,6,-tetramethyl piperidine, bis(3,5-di-tert-butyl-4-hydroxy benzyl monoethyl phosphonate) nickel, bis (1,2,2,6,6-pentamethyl piperidinol) sebacate, bis(1,2,2,6,6-pentamethyl-4-piperidinyl) sebacate, poly(4-hydroxy-2,2,6,6-tetramethyl-1-piperidinyl ethanol) succinate, poly {[6-[(1,1,3,3-tetramethylbutyl) amino]]-1,3,5-triazine-2,4-[(2,2,6,6,-tetramethyl piperidinyl)]}amide, poly[6-[(1,1,3,3-tetramethyl butyl)amine]-1,3,5-triazine-2,4-diyl](2,2,6,6-tetramethyl) piperidine, 1-(methyl)-8-(1,2,2,6,6-pentamethyl-4-piperidinyl) sebacate, and bis (1-octoxyl-2,2,6,6-tetramethyl-4-piperidinyl) sebacate.

The present invention also requests to protect a manufacturing method for the above extruded solar power back panel, wherein the method comprises the following steps: adding materials of the inner layer, the middle layer, and the outer layer, at a ratio, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

According to another corresponding technical solution, an extruded solar power back panel comprises an inner layer and an outer layer arranged from the inside to the outside sequentially, the mass ratio of the inner layer to the outer layer being 10-40:10-80; and

the total thickness of the extruded solar power back panel is 0.1-0.6 mm;

wherein the inner layer comprises the following constituents in parts by mass:

| | |
|---|---|
| polyethylene | 15-85 parts |
| polypropylene | 15-85 parts |
| filler | 0.5-20 parts |
| additive | 0.1-5 parts; |

the polyethylene is one or a mixture of several selected from the group consisting of linear low-density polyethylene, low-density polyethylene, medium-density polyethylene, and copolymers thereof, its density is 0.860-0.940 g/cm³, its DSC melting point is 50-135° C., and its melt flow rate is 0.1-40 g/10 min (2.16 kg, 190° C.), and high-density polyethylene, ultra high-density polyethylene, or a copolymer thereof may be selected, and the density is greater than 0.940 g/cm³; the polypropylene is one or a mixture of several selected from the group consisting of polypropylene homopolymer, polypropylene random copolymer, and polypropylene block copolymer, its DSC melting point is 110-168° C., and its melt flow rate is 0.1-20 g/10 min (2.16 kg, 230° C.); the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;

the outer layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of several selected from the group consisting of polypropylene homopolymer, polypropylene random copolymer, and polypropylene block copolymer; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers.

Preferably, the polypropylene in the outer layer is one or a mixture of two selected from the group consisting of polypropylene homopolymer and polypropylene block copolymer.

The present invention also requests to protect a manufacturing method for the above extruded solar power back panel, wherein the method comprises the following steps: adding materials of the inner layer and the outer layer, at a ratio, into a screw A and a screw B, respectively, of a two-layer sheet co-extrusion unit, simultaneously melting and extruding the materials at the screw extruder, and obtaining the extruded solar power back panel through casting, cooling, pulling, and rolling.

According to another corresponding technical solution, an extruded solar power back panel comprises an inner layer, a middle layer, and an outer layer arranged from the inside to the outside sequentially, wherein the inner layer comprises the following constituents in parts by mass:

| | |
|---|---|
| constituent A | 15-85 parts |
| polypropylene | 15-85 parts |
| filler | 0.5-20 parts |
| additive | 0.1-5 parts; |

the constituent A is a polyethylene graft, or the constituent A is a mixture of polyethylene and a polyethylene graft;

the middle layer comprises the following constituents in parts by mass:

| | |
|---|---|
| polypropylene | 75-99 parts |
| constituent B | 1-25 parts |
| filler | 0.5-20 parts |
| additive | 0.1-5 parts; |

the constituent B is a polyethylene graft, or the constituent A is a mixture of polyethylene and a polyethylene graft;

the outer layer comprises the following constituents in parts by mass:

| | |
|---|---|
| polypropylene | 75-99 parts |
| constituent C | 1-25 parts |
| filler | 0.5-20 parts |
| additive | 0.1-5 parts; |

the constituent C is a polyethylene graft, or the constituent A is a mixture of polyethylene and a polyethylene graft.

Preferably, the inner layer, the middle layer, and the outer layer have the same or different polyethylene, which is one or more selected from the group consisting of polyethylene and polyethylene grafts, respectively; and

the polyethylene graft is one or more selected from the group consisting of maleic anhydride grafted polyethylene, acrylic acid grafted polyethylene, and silane grafted polyethylene.

In the above technical solutions, the polyethylene is one or a mixture of several selected from the group consisting of linear low-density polyethylene, low-density polyethylene, medium-density polyethylene, high-density polyethylene, ultra high-density polyethylene, and copolymers thereof;

the filler is an inorganic filler and/or an organic filler; and

the organic filler is selected from the group consisting of polyethylene terephthalate, polybutylene terephthalate, polyamide, polycarbonate, polyethylene naphthalate, polystyrene, melamine resin, cyclic olefin copolymers, polyethylene thioether, polyimide, polyethyl ether ketone, and polyphenylene sulfide; since these organic fillers are incompatible with polypropylene resins, they form good pores during stretching and are therefore preferred.

Preferably, the filler is pretreated, and the pretreatment method comprises aluminum coating, silicon coating, titanate pretreatment, and silane coupling agent pretreatment. The above filler may also not be pretreated.

In the above technical solutions, the additive is one or more selected from the group consisting of antioxidants, UV absorbents, light stabilizers, heat stabilizers, and silane.

Preferably, the mass ratio of the inner layer to the middle layer to the outer layer is 5-70:20-80:5-60.

Preferably, the total thickness of the extruded solar power back panel is 0.1-0.6 mm.

Preferably, polyethylene in the constituent A of the inner layer is one or a mixture of several selected from the group consisting of linear low-density polyethylene, low-density polyethylene, medium-density polyethylene, and copolymers thereof, its density is 0.860-0.940 g/cm³, its DSC melting point is 50-135° C., and its melt flow rate is 0.1-40 g/10 min (2.16 kg, 190° C.);

for polypropylene in the inner layer, the middle layer, and the outer layer, the DSC melting point is 110-175° C., and the melt flow rate is 0.1-20 g/10 min (2.16 kg, 230° C.).

Preferably, the inner layer, the middle layer, and the outer layer have the same or different polyethylene grafts, which are one or more selected from the group consisting of maleic anhydride grafted polyethylene, acrylic acid grafted polyethylene, and silane grafted polyethylene, respectively.

The present invention also requests to protect a manufacturing method for the above extruded solar power back panel, wherein the method comprises the following steps: adding materials of the inner layer, the middle layer, and the outer layer, at a ratio, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

According to another corresponding technical solution, an extruded solar power back panel comprises an inner layer and an outer layer arranged from the inside to the outside sequentially, wherein the inner layer comprises the following constituents in parts by mass:

| | |
|---|---|
| constituent D | 15-85 parts |
| polypropylene | 15-85 parts |
| filler | 0.5-20 parts |
| additive | 0.1-5 parts; |

the constituent D is a polyethylene graft, or the constituent D is a mixture of polyethylene and a polyethylene graft;

the outer layer comprises the following constituents in parts by mass:

| | |
|---|---|
| polypropylene | 75-99 parts |
| constituent E | 1-25 parts |
| filler | 0.5-20 parts |
| additive | 0.1-5 parts; |

the constituent E is a polyethylene graft, or the constituent D is a mixture of polyethylene and a polyethylene graft.

The present invention also requests to protect a manufacturing method for the above extruded solar power back panel, wherein the method comprises the following steps: adding materials of the inner layer and the outer layer, at the ratio, into a screw A and a screw B, respectively, of a two-layer sheet co-extrusion unit, simultaneously melting and extruding the materials at the screw extruder, and obtaining the extruded solar power back panel through casting, cooling, pulling, and rolling.

According to another corresponding technical solution, an extruded solar power back panel comprises an inner layer, a middle layer, and an outer layer arranged from the inside to the outside sequentially, wherein the inner layer comprises the following constituents in parts by mass:

| | |
|---|---|
| polyethylene | 15-85 parts |
| constituent F | 15-85 parts |
| filler | 0.5-20 parts |
| additive | 0.1-5 parts; |

the constituent F is a polypropylene graft, or the constituent F is a mixture of polypropylene and a polypropylene graft;

the middle layer comprises the following constituents in parts by mass:

| | |
|---|---|
| constituent G | 75-99 parts |
| polyethylene | 1-25 parts |
| filler | 0.5-20 parts |
| additive | 0.1-5 parts; |

the constituent G is a polypropylene graft, or the constituent G is a mixture of polypropylene and a polypropylene graft;

the outer layer comprises the following constituents in parts by mass:

| | |
|---|---|
| constituent H | 75-99 parts |
| polyethylene | 1-25 parts |
| filler | 0.5-20 parts |
| additive | 0.1 -5 parts; |

the constituent H is a polypropylene graft, or the constituent H is a mixture of polypropylene and a polypropylene graft.

The present invention also requests to protect a manufacturing method for the above extruded solar power back panel, wherein the method comprises the following steps: adding materials of the inner layer, the middle layer, and the outer layer, at a ratio, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

According to another corresponding technical solution, an extruded solar power back panel comprises an inner layer and an outer layer arranged from the inside to the outside sequentially, wherein the inner layer comprises the following constituents in parts by mass:

| | |
|---|---|
| polyethylene | 15-85 parts |
| constituent J | 15-85 parts |
| filler | 0.5-20 parts |
| additive | 0.1-5 parts; |

the constituent J is a polypropylene graft, or the constituent J is a mixture of polypropylene and a polypropylene graft;

the outer layer comprises the following constituents in parts by mass:

| | |
|---|---|
| constituent K | 75-99 parts |
| polyethylene | 1-25 parts |
| filler | 0.5-20 parts |
| additive | 0.1-5 parts; |

the constituent K is a polypropylene graft, or the constituent K is a mixture of polypropylene and a polypropylene graft.

The present invention also requests to protect a manufacturing method for the above extruded solar power back panel, wherein the method comprises the following steps: adding materials of the inner layer and the outer layer, at a ratio, into a screw A and a screw B, respectively, of a two-layer sheet co-extrusion unit, simultaneously melting and extruding the materials at the screw extruder, and obtaining the extruded solar power back panel through casting, cooling, pulling, and rolling.

In all the above parallel technical solutions, the polyethylene comprises polyethylene homopolymers and ethylene copolymers, wherein the ethylene copolymer comprises binary ethylene copolymers and ethylene terpolymers, wherein the binary copolymer specifically comprises: ethylene-α olefin copolymers (i.e., POE, wherein a olefin is a monoolefin with the double bond at the end of a molecular chain, mainly including propylene, 1-butene, 1-pentene, 4-methyl-1-pentene, 1-hexene, 1-octene, and the like), ethylene-vinyl acetate copolymers, ethylene-acrylic acid copolymers, ethylene-ethyl acrylate copolymers, ethylene-methyl methacrylate copolymers, ethylene-methyl acrylate copolymers, and the like; wherein the terpolymers specifically comprises: ethylene-propylene-butadiene terpolymers, ethylene-N-butyl acrylate-carbonyl terpolymers, ethylene-N-butyl acrylate-glycidyl ester terpolymers, ethylene-vinyl acetate-vinyl alcohol terpolymers, and the like.

The polyethylene graft comprises maleic anhydride graft, silane graft, and acrylic acid graft of polyethylene homopolymers, and maleic anhydride graft, silane graft, and acrylic acid graft of the above ethylene copolymers.

The polypropylene comprises polypropylene homopolymer, polypropylene block copolymer, and polypropylene random copolymer; wherein the polypropylene homopolymer comprises isotactic polypropylene, atactic polypropylene, and syndiotactic polypropylene;

The polypropylene block copolymer and polypropylene random copolymer comprise binary copolymers and terpolymers; wherein the binary copolymers include block and random copolymers of propylene-styrene and block and random copolymers of propylene-α olefin, wherein a olefin mainly includes ethylene, 1-butene, 1-pentene, 4-methyl-1-pentene, 1-hexene, 1-octene, and the like. The terpolymers are block and random copolymers of ethylene-propylene-butene.

The polypropylene graft comprises maleic anhydride graft, silane graft, and acrylic acid graft of the above polypropylene homopolymer, polypropylene block copolymer, and polypropylene random copolymer.

The filler is an inorganic filler and/or an organic filler; and the organic filler is selected from the group consisting of polyethylene terephthalate, polybutylene terephthalate, polyamide, polycarbonate, polyethylene naphthalate, polystyrene, melamine resin, cyclic olefin copolymers, polyethylene thioether, polyimide, polyethyl ether ketone, and polyphenylene sulfide; the inorganic filler is one or more selected from the group consisting of glass fiber, carbon fiber, mica powder, talc powder, calcium carbonate, kaolin, wollastonite, and titanium dioxide. Preferably, the filler is pretreated, and the pretreatment method comprises aluminum coating, silicon coating, titanate pretreatment, and silane coupling agent pretreatment. The above filler may also not be pretreated.

The additive is one or more selected from the group consisting of antioxidants, UV absorbents, light stabilizers, heat stabilizers, and silane.

The antioxidant is one or more selected from the group consisting of bis(3,5-tert-butyl-4-hydroxy phenyl) thioether, 2,6-tert-butyl-4-methyl phenol, 2,8-di-tert-butyl-4-methyl phenol, pentaerythritol tetra[β-(3′,5′-di-tert-butyl-4-hydroxy phenyl) propionate], tert-butyl p-hydroxyanisole, 2,6-di-tert-butylated hydroxy toluene, tert-butylhydroquinone, 2,6-di-tert-butyl phenol, 2,2′-thio bis(4-methyl-6-tert-butyl phenol), 4,4′-thiobis(6-tert-butyl m-cresol), N,N′-di-s-butyl p-phenylene diamine, s-butyl p-phenylenediamine, 4,4′-methylene bis(2,6-di-tert-butyl phenol), 2,2′-methylene bis(4-methyl-6-tert-butyl phenol), didodecyl thiodipropionate, dilauryl thiodipropionate, 2,6-di-tert-butyl-p-cresol, 2,6-di-tert-butyl-p-cresol, 3,5-di-tert-butyl-4-hydroxy benzyl diethyl phosphonate, 4-[(4,6-dioctyl thio-1,3,5-triazine-2-yl)amino]-2,6-di-tert-butyl phenol, and 1,3,5-trimethyl-2,4,6-tris(3,5-di-tert-butyl-4-hydroxy benzyl) benzene.

The UV absorbent is one or more selected from the group consisting of phenyl salicylate, 2-(2′-hydroxy-5′-methyl phenyl) benzotriazole, 2,4-dihydroxy benzophenone, 2-hydroxy-4-methoxy benzophenone, 2-hydroxy-4-n-octoxyl benzophenone, resorcinol mono-benzoate, phenyl salicylate, 2-(2-hydroxy-3-tert-butyl-5-methylphenyl)-5-chloro benzotriazole, 2-(2′-hydroxy-3′,5′-di-tert-phenyl)-5-chloro benzotriazole, 2-(2-hydroxy-3,5-di-tert-pentyl phenyl) benzotriazole, 2-(2′-hydroxy-4′-benzoyloxy phenyl)-5-chloro-2H-benzotriazole, 2-(4,6-bis(2,4-dimethylphenyl)-1,3,5-triazine-2-yl)-5-octoxyl phenol, and 2-(4,6-diphenyl-1,3,5-triazine-2)-5-n-hexyloxy phenol.

The light stabilizer is one or more selected from the group consisting of bis(2,2,6,6-tetramethyl-4-piperidinyl) sebacate, tris(1,2,2,6,6,-pentamethyl piperidinyl) phosphite, hexamethyl phosphoramide, 4-benzoyloxy-2,2,6,6,-tetramethyl piperidine, bis(3,5-di-tert-butyl-4-hydroxy benzyl monoethyl phosphonate) nickel, bis(1,2,2,6,6-pentamethyl piperidinol) sebacate, bis (1,2,2,6,6-pentamethyl-4-piperidinyl) sebacate, poly(4-hydroxy-2,2,6,6-tetramethyl-1-piperidinyl ethanol) succinate, poly{[6-[(1,1,3,3-tetramethylbutyl) amino]]-1,3,5-triazine-2,4-[(2,2,6,6,-tetramethyl piperidinyl)]}amide, poly[6-[(1,1,3,3-tetramethyl butyl)amine]-1,3,5-triazine-2,4-diyl](2,2,6,6-tetramethyl) piperidine, 1-(methyl)-8-(1,2,2,6,6-pentamethyl-4-piperidinyl) sebacate, and bis (1-octoxyl-2,2,6,6-tetramethyl-4-piperidinyl) sebacate.

The heat stabilizer may be one or more selected from the group consisting of dibutyl tin dilaurate, di-n-butyltin monobutyl maleate, n-butyltin dodecanethiol, lead stearate, calcium stearate, barium stearate, epoxidized soybean oil, epoxidized linseed oil, butyl epoxystearate, trialkyl phosphite, mixed alkyl and aryl esters, trithio alkyl compounds, pentaerythritol, and sorbitol.

In the description above, the extruded solar power back panel has a 2-layer structure of an inner layer and an outer layer arranged from the inside to the outside sequentially, or a 3-layer structure of an inner layer, a middle layer, and an outer layer arranged from the inside to the outside sequentially; in other words, the solar power back panel according to the present invention can have a 2-layer or 3-layer structure, or can have a structure with 4 layers, 5 layers, or more layers,

The back panel according to the present invention can be used independently as a back panel, or can be used as a substrate film for a solar power back panel to make a composite back panel with other materials, such as fluorine-contained films, PET, and fluorocarbon resins.

The mechanism of the present invention is as follows: the addition of highly rigid polypropylene to the inner layer not only ensures the bonding force between the inner layer and an adhesive film, but also improves an inter-layer bonding force between the inner layer and the polypropylene material in the middle layer, thereby ensuring the mechanical strength of the solar power back panel; wherein polyethylene or its copolymer and polypropylene random copolymer have relatively high melt viscosity and can have a good bonding performance with an EVA film, i.e., having better bonding property; polypropylene homopolymer or polypropylene block copolymer can enhance the bonding property between the inner layer and the middle layer (the polypropylene material) and improve the interlayer peeling strength of the back panel. Moreover, polypropylene homopolymer or polypropylene block copolymer has relatively high mechanical strength and can improve the rigidity of the inner layer structure, thereby improving the mechanical strength of the solar power back panel; however, the quantity of polypropylene homopolymer or polypropylene block copolymer cannot be too high; otherwise, the bonding force with an EVA film will be weakened.

At the same time, polyethylene or its copolymer is added into materials of the middle layer and the outer layer. Despite that polypropylene has characteristics like excellent electric insulating performance, low water absorption, and low permeation of water vapor, it has poor cold resistance and tends to experience brittle fracture at low temperature. If polypropylene is directly used as the material for the solar power back panel, the requirement for impact resistance at a low temperature cannot be met; therefore, a polyethylene material with good impact resistance at a low temperature is added, which, on one hand, improves the impact resistance at a low temperature of the back panel, and on the other hand, can be tightly bonded to polyethylene in the inner layer material, thereby further improving the interlayer bonding force of the back panel.

In addition, the introduction of grafted materials improves the material interface and improves the compatibility between a filler and a polymer substrate, such that the filler is better dispersed and more homogenous. As a result, the uniformity of the back panel product is improved, and it is ensured that the bonding performance of the back panel does not deteriorate due to poor dispersion of the filler. Therefore, the back panel is ensured to have a relatively high bonding force. At the same time, materials for different layers are highly similar, all of which are olefin-based materials, and grafting agents like maleic anhydride, acrylic acid, and silane have relatively strong bonding property themselves, which further improves the interlayer bonding force of the back panel. Moreover, grafting agents like maleic anhydride, acrylic acid, and silane also give certain polarity to polyethylene and polypropylene-based olefin materials, which can improve the bonding force between the back panel and a polar EVA film. When a sealing frame is added to the laminated components, the surface tension of grated materials can be further improved after corona treatment is performed on the back panel, leading to tighter bonding with the sealing silica gel used for sealing the frame, and improving the sealing performance of the assembly.

By employing the above technical solutions, the present invention has the following advantages compared with the prior art:

1. The present invention designs an extruded solar power back panel by adding highly rigid polypropylene to the inner layer, which not only ensures the bonding force between the back panel and an adhesive film, but also improves an inter-layer bonding force between the inner layer and the polypropylene material in the middle layer; at the same time, polyethylene or its copolymer is added into materials of the middle layer and the outer layer, which can be tightly bonded to polyethylene in the inner layer material, thereby further improving the interlayer bonding force of the back panel; the addition of polyethylene into materials for all three layers improves the impact resistance at a low temperature of the solar power back panel. Experiments have shown that the interlayer peeling force of the back panel according to the present invention can reach above 21 N/cm, leading to an extremely high interlayer bonding force. In addition, the back panel has great bonding property, high blocking performance, high mechanical strength, and resistance to ageing, and excellent impact resistance at a low temperature, which can fully meet the use requirements by a solar power cell assembly;

2. By adding highly rigid polypropylene to the inner layer, the present invention not only ensures the interlayer bonding force between the inner layer and the polypropylene material in the middle layer, but also improves the rigidity of the inner layer structure, thereby significantly improving the mechanical strength of the solar power back panel;

3. By introducing the grafted materials, the present invention ensures that the filler is dispersed, and improves the bonding force of the back panel; the olefin-based materials for grating have certain polarity, which improves the bonding force between the back panel and a polar EVA film, and improves surface tension of the back panel after corona treatment, thereby ensuring the sealing performance of the assembly bonded by silica gel;

4. The manufacturing method according to the present invention is simple and easy for implementation, which is suitable for being promoted in application.

### DETAILED DESCRIPTION OF EMBODIMENTS

The present invention will be further described below with reference to embodiments:

### Embodiment I

An extruded solar power back panel has a 3-layer structure of an inner layer, a middle layer, and an outer layer;

(1) The inner layer structure: add 10 parts of titanium dioxide R960 (DuPont, USA) and 0.3 parts of a silane coupling agent, 3-aminopropyl triethoxysilane KH550 (Danyang Silicone Material Industry Co., Ltd.) into a fast stirring machine, and stir for 30 min at a rotational speed of 600 rpm to obtain a filler pretreated with the silane coupling agent; subsequently, mix homogeneously the above filler pretreated with the silane coupling agent, 67 parts of low-density polyethylene LD100BW (Beijing Yanshan Petrochemical, its density is 0.923 g/cm³, its DSC melting point is 110° C., and its melt flow rate is 1.8 g/10 min at 190° C./2.16 kg), 33 parts of polypropylene copolymer 1300 (Beijing Yanshan Petrochemical, its DSC melting point is 160° C., and its melt flow rate is 1.5 g/10 min at 230° C./2.16 kg), 0.1 parts of an antioxidant, pentaerythritol tetra[β-(3′,5′-di-tert-butyl-4′-hydroxy phenyl) propionate] (Beijing Additive Institute, KY1010), 0.2 parts of a UV absorbent, 2-hydroxy-4-n-octoxyl benzophenone (Beijing Additive Institute, GW531), and 0.2 parts of a light stabilizer, bis(2,2,6,6-tetramethyl-4-piperidinyl) sebacate (Beijing Additive Institute, GW480); and add the homogeneously mixed materials into a screw A of a three-layer sheet co-extrusion unit, the screw has a diameter of 75 mm and an aspect ratio of 33;

(2) The middle layer structure: add 10 parts of titanium dioxide R960 and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 94 parts of polypropylene block copolymer K8303 (Beijing Yanshan Petrochemical, its DSC melting point is 163° C., and its melt flow rate is 2 g/10 min at 230° C./2.16 kg), 6 parts of low-density polyethylene LD100BW, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw B of the three-layer sheet co-extrusion unit, the screw has a diameter of 75 mm and an aspect ratio of 33;

(3) The outer layer structure: add 10 parts of titanium dioxide R960 and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 96 parts of polypropylene copolymer 1300, 4 parts of low-density polyethylene LD100BW, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw C of the three-layer sheet co-extrusion unit, the screw has a diameter of 75 mm and an aspect ratio of 33;

(4) Simultaneously melt and extrude the three materials for the inner layer, the middle layer, and the outer layer at the screw extruder, control the temperature between 180 and 240° C., the rotational speed at 100 rpm, and the residence time of the materials in the screw between 2 and 4 min, distribute the materials of the three layers inside a distributor at a ratio of 30/40/30, then enter a T-shaped die, the die width being 1200 mm, and obtain a finished product S through processes like cooling, pulling, and rolling, the temperature of three-roll cooling water being 60-70° C. and the pulling velocity being 3-4 m/min. The product has a thickness of 0.33 mm and a width of 1000 mm; see Table 1 for detection results.

### Embodiment II

An extruded solar power back panel has a 2-layer structure of an inner layer and an outer layer;

(1) The inner layer structure: add 10 parts of titanium dioxide R960, 10 parts of talc powder (Shunxin Mineral Product Processing Factory of Lingshou County) and 0.3 parts of a silane coupling agent, 3-glycidoxypropyltrimethoxy silane KH560 (Danyang Silicone Material Industry Co., Ltd.) into a fast stirring machine, and stir for 30 min at a rotational speed of 600 rpm to obtain a filler pretreated with the silane coupling agent; subsequently, mix homogeneously the above filler pretreated with the silane coupling agent, 34 parts of linear low-density polyethylene LLDPE7042 (Sinopec Yangzi Petrochemical Co., Ltd., its density is 0.918 g/cm³, its DSC melting point is 121° C., and its melt flow rate is 2 g/10 min at 230° C./2.16 kg), 33 parts of polypropylene random copolymer R370Y (Korean SK Group, its DSC melting point is 164° C., and its melt flow rate is 18 g/10 min at 230° C./2.16 kg), 33 parts of polypropylene block copolymer K8303, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(2) The outer layer structure: add 10 parts of titanium dioxide R960, 10 parts of talc powder, and 0.3 parts of a silane coupling agent, 3-glycidoxypropyltrimethoxy silane KH560 into a fast stirring machine, and stir for 30 min at a rotational speed of 600 rpm to obtain a filler pretreated with the silane coupling agent; subsequently, mix homogeneously the above filler pretreated with the silane coupling agent, 97 parts of polypropylene block copolymer K8303, 3 parts of linear low-density polyethylene LLDPE7042, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw B of the three-layer sheet co-extrusion unit, the screw has a diameter of 75 mm and an aspect ratio of 33;

(3) Simultaneously melt and extrude the two materials for the inner layer and the outer layer at the screw extruder, control the temperature between 180 and 240° C., the rotational speed at 100 rpm, and the residence time of the materials in the screw between 2 and 4 min, distribute the materials of the two layers inside a distributor at a ratio of 40/60, then enter a T-shaped die, the die width being 1200 mm, and obtain a finished product S2 through processes like cooling, pulling, and rolling, the temperature of three-roll cooling water being 60-70° C. and the pulling velocity being 3-4 m/min. The product has a thickness of 0.33 mm and a width of 1000 mm; see Table 1 for detection results.

### Embodiment III

An extruded solar power back panel has a 3-layer structure of an inner layer, a middle layer, and an outer layer;

(1) The inner layer structure: add 10 parts of titanium dioxide R960, 10 parts of talc powder, 10 parts of sericite powder GA5 (Chuzhou Gerui Mining Co., Ltd.) and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 67 parts of low-density polyethylene LD100BW, 33 parts of polypropylene block copolymer K8303, 0.1 parts of an antioxidant, pentaerythritol tetra[β-(3′, 5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(2) The middle layer structure: add 10 parts of titanium dioxide R960, 10 parts of talc powder, 10 parts of sericite powder GA5, and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 26 parts of polypropylene block copolymer K8303, 28 parts of polypropylene random copolymer R370Y, 38 parts of polypropylene copolymer 1300, 8 parts of low-density polyethylene LD100BW, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw B of the three-layer sheet co-extrusion unit, the screw has a diameter of 75 mm and an aspect ratio of 33;

(3) The outer layer structure: add 10 parts of titanium dioxide R960, 10 parts of talc powder, 10 parts of sericite powder GA5, and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 38 parts of polypropylene copolymer 1300, 58 parts of polypropylene block copolymer K8303, 4 parts of low-density polyethylene LD100BW, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw C of the three-layer sheet co-extrusion unit, the screw has a diameter of 75 mm and an aspect ratio of 33;

(4) Simultaneously melt and extrude the three materials for the inner layer, the middle layer, and the outer layer at the screw extruder, control the temperature between 180 and 240° C., the rotational speed at 100 rpm, and the residence time of the materials in the screw between 2 and 4 min, distribute the materials of the three layers inside a distributor at a ratio of 20/50/30, then enter a T-shaped die, the die width being 1200 mm, and obtain a finished product S3 through processes like cooling, pulling, and rolling, the temperature of three-roll cooling water being 60-70° C. and the pulling velocity being 3-4 m/min. The product has a thickness of 0.33 mm and a width of 1000 mm; see Table 1 for detection results.

### Embodiment IV

An extruded solar power back panel has a 3-layer structure of an inner layer, a middle layer, and an outer layer;

(1) The inner layer structure: add 10 parts of titanium dioxide R960 and 3 parts of an inorganic oxide, Al₂O₃—SiO₂, into a fast stirring machine, and stir for 30 min at a rotational speed of 600 rpm to obtain titanium dioxide pretreated with aluminum-silicon coating; subsequently, mix homogeneously the above pretreated titanium dioxide, 5 parts of an organic filler, polyethylene terephthalate, 64 parts of maleic anhydride grafted polyethylene, 36 parts of polypropylene random copolymer R370Y, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(2) The middle layer structure: add 10 parts of titanium dioxide R960 and 3 parts of an inorganic oxide, Al₂O₃—SiO₂, into a fast stirring machine, and stir for 30 min at a rotational speed of 600 rpm to obtain titanium dioxide pretreated with aluminum-silicon coating; subsequently, mix homogeneously the above pretreated titanium dioxide, 5 parts of an organic filler, polyethylene terephthalate, 20 parts of maleic anhydride grafted polyethylene, 80 parts of polypropylene block copolymer K8303, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(3) The outer layer structure: add 10 parts of titanium dioxide R960 and 3 parts of an inorganic oxide, Al₂O₃—SiO₂, into a fast stirring machine, and stir for 30 min at a rotational speed of 600 rpm to obtain titanium dioxide pretreated with aluminum-silicon coating; subsequently, mix homogeneously the above pretreated titanium dioxide, 5 parts of an organic filler, polyethylene terephthalate, 20 parts of maleic anhydride grafted polyethylene, 50 parts of polypropylene block copolymer K8303, 43 parts of polypropylene copolymer 1300, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(4) Simultaneously melt and extrude the three materials for the inner layer, the middle layer, and the outer layer at the screw extruder, control the temperature between 180 and 240° C., the rotational speed at 100 rpm, and the residence time of the materials in the screw between 2 and 4 min, distribute the materials of the three layers inside a distributor at a ratio of 20/50/30, then enter a T-shaped die, the die width being 1200 mm, and obtain a finished product S4 through processes like cooling, pulling, and rolling, the temperature of three-roll cooling water being 60-70° C. and the pulling velocity being 3-4 m/min. The product has a thickness of 0.33 mm and a width of 1000 mm; see Table 2 for detection results.

### Embodiment V

Other constituents and quantities thereof, as well as the preparation process are all the same as those in Embodiment IV. The difference is that the inner layer material selects 80 parts of maleic anhydride grafted polyethylene and 80 parts of maleic anhydride grafted polypropylene; the middle layer material selects 20 parts of maleic anhydride grafted polyethylene and 80 parts of maleic anhydride grafted polypropylene; and the outer layer material selects 20 parts of maleic anhydride grafted polyethylene and 90 parts of maleic anhydride grafted polypropylene; the finished product is marked as S5.

### Embodiment VI

Other constituents and quantities thereof, as well as the preparation process are all the same as those in Embodiment IV. The difference is that the inner layer material selects 70 parts of low-density polyethylene LD100BW and 83 parts of maleic anhydride grafted polypropylene; the middle layer material selects 13 parts of low-density polyethylene LD100BW, 10 parts of high-density polyethylene 5000S, and 70 parts of maleic anhydride grafted polypropylene; and the outer layer material selects 20 parts of high-density polyethylene 5000S and 90 parts of maleic anhydride grafted polypropylene; the finished product is marked as S6.

### Embodiment VII

In this embodiment, a back panel material having a 2-layer structure of an inner layer and an outer layer is prepared, wherein all constituents and quantities thereof are the same as the raw materials and quantities thereof used by the inner layer and the outer layer in Embodiment IV. The difference is that the melting and co-extrusion process uses a 2-layer sheet co-extrusion unit. The finished product is marked as S7.

### Embodiment VIII

In this embodiment, a back panel material having a 2-layer structure of an inner layer and an outer layer is prepared, wherein all constituents and quantities thereof are the same as the raw materials and quantities thereof used by the inner layer and the outer layer in Embodiment V. The difference is that the melting and co-extrusion process uses a 2-layer sheet co-extrusion unit. The finished product is marked as S8.

### Embodiment IX

In this embodiment, a back panel material having a 2-layer structure of an inner layer and an outer layer is prepared, wherein all constituents and quantities thereof are the same as the raw materials and quantities thereof used by the inner layer and the outer layer in Embodiment VI. The difference is that the melting and co-extrusion process uses a 2-layer sheet co-extrusion unit. The finished product is marked as S9.

### Comparative Example I

(1) Add 10 parts of titanium dioxide R960 and 0.3 parts of a silane coupling agent KH560 into a fast stirring machine, and stir for 30 min at a rotational speed of 600 rpm; subsequently, add 100 parts of an EVA resin, 0.2 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.1 parts of a light stabilizer, bis(2,2,6,6-tetramethyl-4-piperidinyl) sebacate to mix homogeneously; and add the homogeneously mixed materials into a screw A of a three-layer sheet co-extrusion unit, the screw has a diameter of 60 mm and an aspect ratio of 33;

(2) Add 10 parts of titanium dioxide R960 and 0.3 parts of a silane coupling agent KH560 into a fast stirring machine, and stir for 30 min at a rotational speed of 600 rpm; subsequently, mix homogeneously the treated titanium dioxide, 50 parts of polypropylene block copolymer K8303, and 50 parts of high-density polyethylene 5000S, and add them into a twin-screw extruder for granulation by melting and extrusion; add 100 parts of the above prepared finished product into the fast stirring machine, add 0.2 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.1 parts of a light stabilizer, bis(2,2,6,6-tetramethyl-4-piperidinyl) sebacate to mix homogeneously; and add the homogeneously mixed materials into a screw B of the three-layer sheet co-extrusion unit, the screw has a diameter of 90 mm and an aspect ratio of 33;

(3) Add 10 parts of titanium dioxide R960 and 0.3 parts of a silane coupling agent KH560 into a fast stirring machine, and stir for 30 min at a rotational speed of 600 rpm; subsequently, add 100 parts of an EVA resin, 0.2 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.1 parts of a light stabilizer, bis(2,2,6,6-tetramethyl-4-piperidinyl) sebacate to mix homogeneously; and add the homogeneously mixed materials into a screw C of the three-layer sheet co-extrusion unit, the screw has a diameter of 60 mm and an aspect ratio of 33;

(4) Simultaneously melt and extrude the above three materials at the screw extruder, control the temperature between 180 and 240° C., the rotational speed at 100 rpm, and the residence time of the materials in the screw between 2 and 4 min, distribute the materials of the three layers inside a distributor at a ratio of 20/50/30, then enter a T-shaped die, the die width being 1200 mm, and obtain a finished product S3 through processes like cooling, pulling, and rolling, the temperature of three-roll cooling water being 60-70° C. and the pulling velocity being 3-4 m/min. The product has a thickness of 0.33 mm and a width of 1000 mm, i.e., B1; see Table 1 for detection results.

### Comparative Example II

(1) Mix homogeneously polypropylene resin, an organic UV absorbent, 5% 2-hydroxy-4-n-methoxyl benzophenone, and an inorganic antioxidant with a high-speed mixer, extrude to granulate with a twin-screw extruder, and obtain a modified polyolefin resin;

(2) Mix homogeneously 85% POE resin, 5% photoinitiator, 5% photosensitizer, and 5% anti-bisphenol A phosphite solution with a high-speed mixer, dry the solvent at 50° C. in an oven, and obtain a modified POE mixture;

(3) Coat an anti-hydrolysis coating having a thickness of 5 μm on the surface of a PET film, and obtain an anti-hydrolysis PET film;

(4) Melt and extrude the modified polypropylene resin obtained in the step 1 and the modified POE mixture obtained in the step 2 through an extruder to obtain a modified polyolefin film and a modified POE film, which are attached, respectively, to two sides of the anti-hydrolysis PET film in the step 3 that has been subjected to corona surface treatment to obtain a composite film having a 3-layer structure, which is marked as B2; see Table 1 for detection results.

### Comparative Example III

(1) The inner layer structure: add 10 parts of titanium dioxide R960 and 0.2 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 20 parts of low-density polyethylene LD100BW, 80 parts of linear low-density polyethylene LLDPE7042, 100 parts of polypropylene random copolymer R370Y, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw A of a three-layer sheet co-extrusion unit, the screw has a diameter of 75 mm and an aspect ratio of 33;

(2) The middle layer structure: add 10 parts of titanium dioxide R960 and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 100 parts of polypropylene copolymer 1300, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw B of the three-layer sheet co-extrusion unit, the screw has a diameter of 75 mm and an aspect ratio of 33;

(3) The outer layer structure: add 10 parts of titanium dioxide R960 and 0.3 parts of a silane coupling agent, 3-aminopropyl triethoxysilane KH550 into a fast stirring machine, and stir for 30 min at a rotational speed of 600 rpm to obtain a filler pretreated with the silane coupling agent; subsequently, mix homogeneously the above filler pretreated with the silane coupling agent, 100 parts of polypropylene block copolymer K8303, 0.1 parts of an antioxidant, pentaerythritol tetra[β-(3′,5′-di-tert-butyl-4′-hydroxy phenyl) propionate], 0.2 parts of a UV absorbent, 2-hydroxy-4-n-octoxyl benzophenone, and 0.2 parts of a light stabilizer, bis(2,2,6,6-tetramethyl-4-piperidinyl) sebacate; and add the homogeneously mixed materials into a screw C of the three-layer sheet co-extrusion unit, the screw has a diameter of 75 mm and an aspect ratio of 33;

(4) Simultaneously melt and extrude the three materials for the inner layer, the middle layer, and the outer layer at the screw extruder, control the temperature between 180 and 240° C., the rotational speed at 100 rpm, and the residence time of the materials in the screw between 2 and 4 min, distribute the materials of the three layers inside a distributor at a ratio of 30/40/30, then enter a T-shaped die, the die width being 1200 mm, and obtain a finished product B3 through processes like cooling, pulling, and rolling, the temperature of three-roll cooling water being 60-70° C. and the pulling velocity being 3-4 m/min. The product has a thickness of 0.33 mm and a width of 1000 mm; see Table 1 for detection results.

See Table 2 for some detection results of the back panel products obtained in Embodiment IV through Embodiment IX and the products obtained in Comparative Examples I through III.

Subsequently, performance testing is conducted on the above embodiments and comparative examples. The specific methods are as follows:

1. Shrinkage Test

The test was conducted according to the testing method prescribed in GB/T 13541, Testing Method for Plastic Films in Electric Applications.

2. Water Vapor Permeation Test

The test was conducted according to the testing method prescribed in GB/T 21529, Testing Method for Water Vapor Permeation of Plastic Films and Thin Sheets.

3. Elastic Modulus Test

The test was conducted according to the testing method prescribed in GB/T1040.3-2006, Measurement of Plastic Tensile Performance, Part 3: Experimental Conditions for Films and Thin Sheets.

4. Saturated Water Absorption Test

The test was conducted according to the testing method prescribed in GB/T1034, Testing Method for Water Absorption of Plastics.

5. Interlayer Peeling Strength Test

The interlayer peeling strength between an inner layer and a middle layer was tested, and the test was conducted according to the testing method prescribed in GB/T2792, Testing Method for 1800 Peeling Strength of Pressure Sensitive Adhesive Tape.

6. Test on Impact Resistance at a Low Temperature

The test was conducted according to the testing methods prescribed in GB/T2423.1-2008, Environmental Test of Electric and Electronic Products, Part 2: Test Methods, Experiment A: low temperature, and GB/T1843-2008, Measurement of Impact Strength of Plastic Cantilever Beam, and the test temperature was −40° C. Prepared notch impact specimens of a cantilever beam were placed in a low temperature box with the preset temperature, and when thermal equilibrium was reached, the specimens were taken out one by one for a quick impact test on a cantilever beam impact tester.

7. Test of Ageing by Humidity and Heat

The ageing by humidity and heat was conducted according to the testing method of ageing by moisture and heat prescribed in IEC 61215: 2005, and the experimental conditions were: a temperature of 85° C., a relative humidity of 85%, and a testing time of 1500 hours.

8. Test of Bonding Strength with EVA Before and after Accelerated Ageing Test at High Temperature (PCT)

The PCT test was conducted according to JESD 22-102A, and the experimental conditions were: relative humidity 100%, 121° C., 2 atm, and 48 hours. The bonding strength between a back panel and EVA was tested according to the testing methods prescribed in GB/T2792, Testing Method for 1800 Peeling Strength of Pressure Sensitive Adhesive Tape.

9. Volume Resistivity Test

The test was conducted according to the testing method prescribed in GB/T1410, Volume Resistivity and Surface Resistivity of Solid Insulating Materials.

10. Breaking Strength and Elongation at Break Test

The test was conducted according to ASTM D638, Standard Testing Method for Plastic Tensile Strength. Samples were taken randomly from different parts of back panels with 5 specimens from each back panel for testing of longitudinal breaking strength and elongation at break, which were used to analyze the uniformity of the back panels.

11. Surface Tension of Samples Before and after Corona Treatment

Surface tension of the back panels after corona treatment was tested according to ASTM D7490-2013, Standard Measurement Method for Measurement of Surface Tension for Solids including Coating, Paint and Substrates.

TABLE 1
Results of performance testing of solar power back
panels in all embodiments and comparative examples

| | | Solar power back panel | | | | | |
|---|---|---|---|---|---|---|---|
| | | S1 | S2 | S3 | B1 | B2 | B3 |
| Shrinkage, % | Longitudinal | 0.8 | 0.7 | 0.6 | 1.0 | 1.5 | 0.8 |
| (150° C., 30 min) | Lateral | 0.5 | 0.3 | 0.2 | 0.5 | 0.8 | 1.0 |

| | | | | | | |
|---|---|---|---|---|---|---|
| Water vapor permeation, g · m⁻² · d⁻¹ | 0.31 | 0.34 | 0.32 | 0.34 | 1.6 | 0.33 |
| (23° C., 85% RH) | | | | | | |
| Elastic modulus (MPa) | 1050 | 983 | 1100 | 820 | 2000 | 1000 |
| Bonding strength with EVA, N/cm | * | * | * | * | 95 | * |
| Saturated water absorption, % | 0.13 | 0.12 | 0.11 | 0.14 | 0.82 | 0.14 |
| (boiling water, 30 min) | | | | | | |
| Interlayer peeling force, N/cm | 24 | 21 | 23 | 22 | 5.0 | 10 |
| Impact resistance at a low temperature, KJ/m² | 32 | 36 | 34 | 3.1 | 1.5 | 4.3 |

| Ageing | Appearance | | No obvious | No obvious | No obvious | No obvious | Yellow, | No obvious |
|---|---|---|---|---|---|---|---|---|
| by | | | discoloration, | discoloration, | discoloration, | discoloration, | stratified, | discoloration, |
| humidity | | | no | no | no | no | embrittlement | no |
| and heat | | | stratification, | stratification, | stratification, | stratification, | | stratification, |
| (85° C., | | | no | no | no | no | | no |
| 85% RH, | | | embrittlement | embrittlement | embrittlement | embrittlement | | embrittlement |
| 1500 h) | Elongation | Longitudinal | 97 | 95 | 99 | 70 | | 75 |
| | at | Lateral | 96 | 97 | 95 | 66 | | 67 |
| | break, % | | | | | | | |

| | | | | | | | |
|---|---|---|---|---|---|---|---|
| PCT | Appearance | No obvious | No obvious | No obvious | Yellow, | Yellow, | No obvious |
| ageing | | discoloration, | discoloration, | discoloration, | stratified, | stratified, | discoloration, |
| | | no | no | no | embrittlement | embrittlement | no |
| | | stratification, | stratification, | stratification, | | | stratification, |
| | | no | no | no | | | no |
| | | embrittlement | embrittlement | embrittlement | | | embrittlement |

| | | | | |
|---|---|---|---|---|
| Bonding strength with | 58 | 65 | 62 | 52 |
| EVA, N/cm | | | | |

| | | | | | | |
|---|---|---|---|---|---|---|
| Volume resistivity, Ω * cm | 5.3 * 10¹⁷ | 3.6 * 10¹⁷ | 9.8 * 10¹⁷ | 3.2 * 10¹⁷ | 8.6 * 10¹⁵ | 3.4 * 10¹⁷ |

* Note: the peeling strength was too high to pull them apart.

TABLE 2
Results of performance testing of solar power back
panels in embodiments 4-9 and comparative examples

| | | | | | | Bonding | |
|---|---|---|---|---|---|---|---|
| | | | | | Interlayer | strength | |
| | | | Elongation at | | peeling | with | Surface |
| | Breaking | | break | | force | EVA | tension |
| Products | strength (MPa) | | (%) | | (N/cm) | (N/cm) | (dyn/cm) |
| S1 | Specimen 1 | 28 | Specimen 1 | 1334 | 24 | * | 38 |
| | Specimen 2 | 38 | Specimen 2 | 999 | | | |
| | Specimen 3 | 46 | Specimen 3 | 1168 | | | |
| | Specimen 4 | 35 | Specimen 4 | 1012 | | | |
| | Specimen 5 | 47 | Specimen 5 | 970 | | | |
| S2 | Specimen 1 | 45 | Specimen 1 | 1234 | 21 | * | 35 |
| | Specimen 2 | 37 | Specimen 2 | 1432 | | | |
| | Specimen 3 | 26 | Specimen 3 | 908 | | | |
| | Specimen 4 | 51 | Specimen 4 | 894 | | | |
| | Specimen 5 | 43 | Specimen 5 | 1070 | | | |
| S3 | Specimen 1 | 41 | Specimen 1 | 1213 | 23 | * | 37 |
| | Specimen 2 | 27 | Specimen 2 | 1342 | | | |
| | Specimen 3 | 36 | Specimen 3 | 1098 | | | |
| | Specimen 4 | 46 | Specimen 4 | 870 | | | |
| | Specimen 5 | 39 | Specimen 5 | 1392 | | | |
| S4 | Specimen 1 | 46 | Specimen 1 | 1340 | 35 | * | 47 |
| | Specimen 2 | 47 | Specimen 2 | 1365 | | | |
| | Specimen 3 | 46 | Specimen 3 | 1368 | | | |
| | Specimen 4 | 46 | Specimen 4 | 1342 | | | |
| | Specimen 5 | 47 | Specimen 5 | 1370 | | | |
| S5 | Specimen 1 | 50 | Specimen 1 | 1502 | 33 | * | 45 |
| | Specimen 2 | 52 | Specimen 2 | 1498 | | | |
| | Specimen 3 | 52 | Specimen 3 | 1500 | | | |
| | Specimen 4 | 51 | Specimen 4 | 1496 | | | |
| | Specimen 5 | 51 | Specimen 5 | 1488 | | | |
| S6 | Specimen 1 | 47 | Specimen 1 | 1356 | 30 | * | 48 |
| | Specimen 2 | 48 | Specimen 2 | 1349 | | | |
| | Specimen 3 | 48 | Specimen 3 | 1348 | | | |
| | Specimen 4 | 47 | Specimen 4 | 1335 | | | |
| | Specimen 5 | 48 | Specimen 5 | 1329 | | | |
| S7 | Specimen 1 | 46 | Specimen 1 | 1389 | 32 | * | 45 |
| | Specimen 2 | 47 | Specimen 2 | 1398 | | | |
| | Specimen 3 | 47 | Specimen 3 | 1369 | | | |
| | Specimen 4 | 46 | Specimen 4 | 1384 | | | |
| | Specimen 5 | 46 | Specimen 5 | 1394 | | | |
| S8 | Specimen 1 | 51 | Specimen 1 | 1598 | 34 | * | 46 |
| | Specimen 2 | 52 | Specimen 2 | 1584 | | | |
| | Specimen 3 | 52 | Specimen 3 | 1574 | | | |
| | Specimen 4 | 52 | Specimen 4 | 1586 | | | |
| | Specimen 5 | 51 | Specimen 5 | 1562 | | | |
| S9 | Specimen 1 | 48 | Specimen 1 | 1384 | 33 | * | 49 |
| | Specimen 2 | 48 | Specimen 2 | 1387 | | | |
| | Specimen 3 | 47 | Specimen 3 | 1364 | | | |
| | Specimen 4 | 47 | Specimen 4 | 1358 | | | |
| | Specimen 5 | 48 | Specimen 5 | 1349 | | | |
| B1 | Specimen 1 | 37 | Specimen 1 | 1154 | 3.1 | * | 30 |
| | Specimen 2 | 42 | Specimen 2 | 1492 | | | |
| | Specimen 3 | 35 | Specimen 3 | 1057 | | | |
| | Specimen 4 | 45 | Specimen 4 | 1500 | | | |
| | Specimen 5 | 30 | Specimen 5 | 988 | | | |
| B2 | Specimen 1 | 46 | Specimen 1 | 1587 | 1.5 | 95 | 29 |
| | Specimen 2 | 38 | Specimen 2 | 1262 | | | |
| | Specimen 3 | 40 | Specimen 3 | 1289 | | | |
| | Specimen 4 | 32 | Specimen 4 | 965 | | | |
| | Specimen 5 | 52 | Specimen 5 | 1426 | | | |
| B3 | Specimen 1 | 42 | Specimen 1 | 1328 | 4.3 | * | 28 |
| | Specimen 2 | 32 | Specimen 2 | 891 | | | |
| | Specimen 3 | 47 | Specimen 3 | 1485 | | | |
| | Specimen 4 | 29 | Specimen 4 | 956 | | | |
| | Specimen 5 | 34 | Specimen 5 | 1246 | | | |

* Note: the peeling strength was too high to pull them apart.

It can be seen from Table 1 that compared with the 3-layer solar power back panel using EVA in the inner layer (Comparative Example I), the extruded solar power back panel according to the present invention has higher mechanical strength, impact strength at low temperature and better ageing resistance; compared with the solar power back panel using PET as the substrate film (Comparative Example II), the extruded solar power back panel according to the present invention has higher blocking performance, bonding strength, impact strength at low temperature and better ageing resistance, Compared with Comparative Example III, the interlayer peeling force and impact resistance at a low temperature of the solar power back panel according to the present invention have been significantly improved, indicating that the solar power back panel according to the present invention has extremely high interlayer bonding force and impact resistance at a low temperature. After the accelerated ageing test at high temperature (PCT test), the extruded solar power back panel according to the present invention still keeps good appearance and relatively high bonding strength, which extends the service life of the back panel and a solar power cell assembly using the back panel. Therefore, the solar power back panel according to the present invention has high interlayer bonding force, high bonding performance, high blocking performance, high mechanical strength, and excellent impact resistance at a low temperature.

At the same time, it can be seen from Table 2 that the values of breaking strength and elongation at break are not significantly different among samples from different parts after breaking strength and elongation at break tests were performed on samples taken from different parts of the solar power back panel products obtained in Embodiments IV through IX, while the values of breaking strength and elongation at break are significantly different among samples from different parts of the products obtained in Embodiments I through III and Comparative Examples I through III, indicating that the solar power back panel products introduced with grafted polymers have better uniformity;

The interlayer peeling force of the solar power back panel products obtained in Embodiments IV through IX is also greater than that of Embodiments I through III and Comparative Examples I through III, indicating that the introduction of the grafted materials improves the interlayer bonding performance; moreover, the bonding force with EVA film is also higher, indicating that the back panels have excellent bonding performance;

After corona treatment was performed on the products, it can be seen that the surface tension of the products obtained in Embodiments IV through IX is significantly greater than the surface tension of the solar power back panels in Embodiments I through III and Comparative Examples I through III, indicating that the introduction of the grafted materials improves the surface tension after the final corona treatment on the products and can ensure tight bonding between the back panels and the frame sealing silica gel.

The above embodiments are only preferred implementation modes of the present invention, and cannot be used to limit the scope of the present invention. Any non-substantive modifications and substitutions made by a person skilled in the art on the basis of the present invention shall be encompassed by the scope of the present invention.

1. An extruded solar power back panel, comprising an inner layer, a middle layer, and an outer layer arranged from the inside to the outside sequentially, wherein the mass ratio of the inner layer to the middle layer to the outer layer is 10-40:40-80:10-40; and
the total thickness of the extruded solar power back panel is 0.1-0.6 mm;
wherein the inner layer comprises the following constituents in parts by mass:

| | |
|---|---|
| polyethylene | 15-85 parts |
| polypropylene | 15-85 parts |
| filler | 0.5-20 parts |
| additive | 0.1-5 parts; |

the polyethylene is one or a mixture of several selected from the group consisting of linear low-density polyethylene, low-density polyethylene, medium-density polyethylene, and copolymers thereof, its density is 0.860-0.940 g/cm³, its DSC melting point is 50-135° C., and its melt flow rate is 0.1-40 g/10 min (2.16 kg, 190° C.); the polypropylene is one or a mixture of several selected from the group consisting of polypropylene homopolymer, polypropylene random copolymer, and polypropylene block copolymer, its DSC melting point is 110-168° C., and its melt flow rate is 0.1-20 g/10 min (2.16 kg, 230° C.); the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;
the middle layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of several selected from the group consisting of polypropylene homopolymer, polypropylene random copolymer, and polypropylene block copolymer; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;
the outer layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of two selected from the group consisting of polypropylene homopolymer and polypropylene block copolymer; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers.

2. The extruded solar power back panel according to claim 1, wherein the silane coupling agent is one or more selected from the group consisting of vinyl trimethoxysilane, vinyl triethoxysilane, isobutyl triethoxysilane, 3-aminopropyl triethoxysilane, 3-aminopropyl trimethoxysilane and 3-glycidyl aminopropyl trimethoxysilane, vinyl tris(β-methoxyethoxy) silane, γ-methacryloyloxypropyl trimethoxy silane, γ-mercapto-propyl triethoxysilane, N-(β-amino ethyl)-γ-aminopropylmethyl dimethoxysilane, N-(β-amino ethyl)-γ-aminopropyl triethoxysilane, N-(β-amino ethyl)-γ-amino propyl trimethoxysilane, γ-aminopropyl methyl diethoxysilane, diethylamino methyl triethoxysilane, anilino methyl triethoxysilane, dichloro methyl triethoxysilane, bis(γ-triethoxysilylpropyl) tetrasulfide, phenyl trimethoxy silane, phenyl triethoxysilane, and methyl triethoxysilane.

3. The extruded solar power back panel according to claim 1, wherein the antioxidant is one or more selected from the group consisting of bis(3,5-tert-butyl-4-hydroxy phenyl) thioether, 2,6-tert-butyl-4-methyl phenol, 2,8-di-tert-butyl-4-methyl phenol, pentaerythritol tetra[β-(3′,5′-di-tert-butyl-4-hydroxy phenyl) propionate], tert-butyl p-hydroxyanisole, 2,6-di-tert-butylated hydroxy toluene, tert-butylhydroquinone, 2,6-di-tert-butyl phenol, 2,2′-thio bis(4-methyl-6-tert-butyl phenol), 4,4′-thiobis(6-tert-butyl m-cresol), N,N′-di-s-butyl p-phenylenediamine, s-butyl p-phenylenediamine, 4,4′-methylene bis(2,6-di-tert-butyl phenol), 2,2′-methylene bis(4-methyl-6-tert-butyl phenol), didodecyl thiodipropionate, dilauryl thiodipropionate, 2,6-di-tert-butyl-p-cresol, 2,6-di-tert-butyl-p-cresol, 3,5-di-tert-butyl-4-hydroxy benzyl diethyl phosphonate, 4-[(4,6-dioctylthio-1,3,5-triazine-2-yl)amino]-2,6-di-tert-butyl phenol, and 1,3,5-trimethyl-2,4,6-tris(3,5-di-tert-butyl-4-hydroxy benzyl)benzene.

4. The extruded solar power back panel according to claim 1, wherein the UV absorbent is one or more selected from the group consisting of phenyl salicylate, 2-(2′-hydroxy-5′-methylphenyl)benzotriazole, 2,4-dihydroxy benzophenone, 2-hydroxy-4-methoxy benzophenone, 2-hydroxy-4-n-octoxyl benzophenone, resorcinol mono-benzoate, phenyl salicylate, 2-(2-hydroxy-3-tert-butyl-5-methylphenyl)-5-chloro benzotriazole, 2-(2′-hydroxy-3′,5′-di-tert-phenyl)-5-chloro benzotriazole, 2-(2-hydroxy-3,5-di-tert-pentyl phenyl) benzotriazole, 2-(2′-hydroxy-4′-benzoyloxy phenyl)-5-chloro-2H-benzotriazole, 2-(4,6-bis(2,4-dimethylphenyl)-1,3,5-triazine-2-yl)-5-octoxyl phenol, and 2-(4,6-diphenyl-1,3,5-triazine-2)-5-n-hexyloxy phenol.

5. The extruded solar power back panel according to claim 1, wherein the light stabilizer is one or more selected from the group consisting of bis(2,2,6,6-tetramethyl-4-piperidinyl) sebacate, tris(1,2,2,6,6,-pentamethyl piperidinyl) phosphite, hexamethylphosphoramide, 4-benzoyloxy-2,2,6,6,-tetramethyl piperidine, bis(3,5-di-tert-butyl-4-hydroxy benzyl monoethyl phosphonate) nickel, bis(1,2,2,6,6-pentamethyl piperidinol) sebacate, bis(1,2,2,6,6-pentamethyl-4-piperidinyl) sebacate, poly(4-hydroxy-2,2,6,6-tetramethyl-1-piperidinyl ethanol) succinate, poly{([6-[(1,1,3,3-tetramethylbutyl) amino]]-1,3,5-triazine-2,4-[(2,2,6,6,-tetramethyl piperidinyl)]}amide, poly[6-[(1,1,3,3-tetramethylbutyl)amine]-1,3,5-triazine-2,4-diyl](2,2,6,6-tetramethyl) piperidine, 1-(methyl)-8-(1,2,2,6,6-pentamethyl-4-piperidinyl) sebacate, and bis (1-octoxyl-2,2,6,6-tetramethyl-4-piperidinyl) sebacate.

6. A manufacturing method for the extruded solar power back panel according to claim 1, wherein the method comprises the following steps: adding materials of the inner layer, the middle layer, and the outer layer, at a ratio according to claim 1, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

7. An extruded solar power back panel, comprising an inner layer and an outer layer arranged from the inside to the outside sequentially, wherein the mass ratio of the inner layer to the outer layer is 10-40:10-80; and
the total thickness of the extruded solar power back panel is 0.1-0.6 mm;
wherein the inner layer comprises the following constituents in parts by mass:

| | |
|---|---|
| polyethylene | 15-85 parts |
| polypropylene | 15-85 parts |
| filler | 0.5-20 parts |
| additive | 0.1-5 parts; |

the polyethylene is one or a mixture of several selected from the group consisting of linear low-density polyethylene, low-density polyethylene, medium-density polyethylene, and copolymers thereof, its density is 0.860-0.940 g/cm³, its DSC melting point is 50-135° C., and its melt flow rate is 0.1-40 g/10 min (2.16 kg, 190° C.); the polypropylene is one or a mixture of several selected from the group consisting of polypropylene homopolymer, polypropylene random copolymer, and polypropylene block copolymer, its DSC melting point is 110-168° C., and its melt flow rate is 0.1-20 g/10 min (2.16 kg, 230° C.); the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers;
the outer layer comprises the following constituents in parts by mass:

| | |
|---|---|
| polypropylene | 75-99 parts |
| polyethylene | 1-25 parts |
| filler | 0.5-20 parts |
| additive | 0.1-5 parts; |

the polypropylene is one or a mixture of several selected from the group consisting of polypropylene homopolymer, polypropylene random copolymer, and polypropylene block copolymer; the polyethylene is one or a mixture of several selected from the group consisting of linear low-density polyethylene, low-density polyethylene, medium-density polyethylene, high-density polyethylene, ultra high-density polyethylene, and copolymers thereof; the filler is one or more selected from the group consisting of glass fiber, carbon fiber, mica powder, talc powder, calcium carbonate, kaolin, wollastonite, and titanium dioxide, and the filler is a filler pre-treated by a silane coupling agent; and the additive is one or more selected from the group consisting of antioxidants, UV absorbents, and light stabilizers.

8. The extruded solar power back panel according to claim 7, wherein the polypropylene in the outer layer is one or a mixture of two selected from the group consisting of polypropylene homopolymer and polypropylene block copolymer.

9. A manufacturing method for the extruded solar power back panel according to claim 7, wherein the method comprises the following steps: adding materials of the inner layer and the outer layer, at a ratio according to claim 7, into a screw A and a screw B, respectively, of a two-layer sheet co-extrusion unit, simultaneously melting and extruding the materials at the screw extruder, and obtaining the extruded solar power back panel through casting, cooling, pulling, and rolling.

10. An extruded solar power back panel, comprising an inner layer, a middle layer, and an outer layer arranged from the inside to the outside sequentially, wherein the inner layer comprises the following constituents in parts by mass:

| | |
|---|---|
| constituent A | 15-85 parts |
| polypropylene | 15-85 parts |
| filler | 0.5-20 parts |
| additive | 0.1-5 parts; |

the constituent A is a polyethylene graft, or the constituent A is a mixture of polyethylene and a polyethylene graft;
the middle layer comprises the following constituents in parts by mass:

| | |
|---|---|
| polypropylene | 75-99 parts |
| constituent B | 1-25 parts |
| filler | 0.5-20 parts |
| additive | 0.1-5 parts; |

the constituent B is a polyethylene graft, or the constituent B is a mixture of polyethylene and a polyethylene graft;
the outer layer comprises the following constituents in parts by mass:

| | |
|---|---|
| polypropylene | 75-99 parts |
| constituent C | 1-25 parts |
| filler | 0.5-20 parts |
| additive | 0.1-5 parts; |

the constituent C is a polyethylene graft, or the constituent C is a mixture of polyethylene and a polyethylene graft.

11. The extruded solar power back panel according to claim 10, wherein the inner layer, the middle layer, and the outer layer have the same or different polyethylene, which is one or more selected from the group consisting of polyethylene and polyethylene grafts, respectively; and
the polyethylene graft is one or more selected from the group consisting of maleic anhydride grafted polyethylene, acrylic acid grafted polyethylene, and silane grafted polyethylene.

12. The extruded solar power back panel according to claim 10, wherein the polyethylene is one or a mixture of several selected from the group consisting of linear low-density polyethylene, low-density polyethylene, medium-density polyethylene, high-density polyethylene, ultra high-density polyethylene, and copolymers thereof;
the filler is an inorganic filler and/or an organic filler; and
the additive is one or more selected from the group consisting of antioxidants, UV absorbents, light stabilizers, heat stabilizers, and silane.

13. The extruded solar power back panel according to claim 12, wherein the filler is pretreated, and the pretreatment method comprises aluminum coating, silicon coating, titanate pretreatment, and silane coupling agent pretreatment.

14. The extruded solar power back panel according to claim 10, wherein the mass ratio of the inner layer to the middle layer to the outer layer is 5-70:20-80:5-60.

15. The extruded solar power back panel according to claim 10, wherein the total thickness of the extruded solar power back panel is 0.1-0.6 mm.

16. The extruded solar power back panel according to claim 10, wherein polyethylene in the constituent A of the inner layer is one or a mixture of several selected from the group consisting of linear low-density polyethylene, low-density polyethylene, medium-density polyethylene, and copolymers thereof, its density is 0.860-0.940 g/cm³, its DSC melting point is 50-135° C., and its melt flow rate is 0.1-40 g/10 min (2.16 kg, 190° C.);
for polypropylene in the inner layer, the middle layer, and the outer layer, the DSC melting point is 110-175° C., and the melt flow rate is 0.1-20 g/10 min (2.16 kg, 230° C.).

17. The extruded solar power back panel according to claim 10, wherein the inner layer, the middle layer, and the outer layer have the same or different polyethylene grafts, which are one or more selected from the group consisting of maleic anhydride grafted polyethylene, acrylic acid grafted polyethylene, and silane grafted polyethylene, respectively.

18. A manufacturing method for the extruded solar power back panel according to claim 10, wherein the method comprises the following steps: adding materials of the inner layer, the middle layer, and the outer layer, at a ratio according to claim 10, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

19. An extruded solar power back panel, comprising an inner layer and an outer layer arranged from the inside to the outside sequentially, wherein the inner layer comprises the following constituents in parts by mass:

| | |
|---|---|
| constituent D | 15-85 parts |
| polypropylene | 15-85 parts |
| filler | 0.5-20 parts |
| additive | 0.1-5 parts; |

the constituent D is a polyethylene graft, or the constituent D is a mixture of polyethylene and a polyethylene graft;
the outer layer comprises the following constituents in parts by mass:

| | |
|---|---|
| polypropylene | 75-99 parts |
| constituent E | 1-25 parts |
| filler | 0.5-20 parts |
| additive | 0.1-5 parts; |

the constituent E is a polyethylene graft, or the constituent E is a mixture of polyethylene and a polyethylene graft.

20. A manufacturing method for the extruded solar power back panel according to claim 19, wherein the method comprises the following steps: adding materials of the inner layer and the outer layer, at a ratio according to claim 19, into a screw A and a screw B, respectively, of a two-layer sheet co-extrusion unit, simultaneously melting and extruding the materials at the screw extruder, and obtaining the extruded solar power back panel through casting, cooling, pulling, and rolling.

21. An extruded solar power back panel, comprising an inner layer, a middle layer, and an outer layer arranged from the inside to the outside sequentially, wherein the inner layer comprises the following constituents in parts by mass:

| | |
|---|---|
| polyethylene | 15-85 parts |
| constituent F | 15-85 parts |
| filler | 0.5-20 parts |
| additive | 0.1-5 parts; |

the constituent F is a polypropylene graft, or the constituent F is a mixture of polypropylene and a polypropylene graft;
the middle layer comprises the following constituents in parts by mass:

| | |
|---|---|
| constituent G | 75-99 parts |
| polyethylene | 1-25 parts |
| filler | 0.5-20 parts |
| additive | 0.1-5 parts; |

the constituent G is a polypropylene graft, or the constituent G is a mixture of polypropylene and a polypropylene graft;
the outer layer comprises the following constituents in parts by mass:

| | |
|---|---|
| constituent H | 75-99 parts |
| polyethylene | 1-25 parts |
| filler | 0.5-20 parts |
| additive | 0.1-5 parts; |

the constituent H is a polypropylene graft, or the constituent H is a mixture of polypropylene and a polypropylene graft.

22. A manufacturing method for the extruded solar power back panel according to claim 21, wherein the method comprises the following steps: adding materials of the inner layer, the middle layer, and the outer layer, at a ratio according to claim 21, into a screw A, a screw B, and a screw C, respectively, of a three-layer sheet co-extrusion unit, simultaneously melting and extruding the materials at the screw extruder, and obtaining the extruded solar power back panel through casting, cooling, pulling, and rolling.

23. An extruded solar power back panel, comprising an inner layer and an outer layer arranged from the inside to the outside sequentially, wherein the inner layer comprises the following constituents in parts by mass:

| | |
|---|---|
| polyethylene | 15-85 parts |
| constituent J | 15-85 parts |
| filler | 0.5-20 parts |
| additive | 0.1-5 parts; |

the constituent J is a polypropylene graft, or the constituent J is a mixture of polypropylene and a polypropylene graft;
the outer layer comprises the following constituents in parts by mass:

| | |
|---|---|
| constituent K | 75-99 parts |
| polyethylene | 1-25 parts |
| filler | 0.5-20 parts |
| additive | 0.1-5 parts; |

the constituent K is a polypropylene graft, or the constituent K is a mixture of polypropylene and a polypropylene graft.

24. A manufacturing method for the extruded solar power back panel according to claim 23, wherein the method comprises the following steps: adding materials of the inner layer and the outer layer, at a ratio according to claim 23, into a screw A and a screw B, respectively, of a two-layer sheet co-extrusion unit, simultaneously melting and extruding the materials at the screw extruder, and obtaining the extruded solar power back panel through casting, cooling, pulling, and rolling.
